(19) United States
(12) Patent Application Publication
(10) Pub. No.: US 2016/0087245 A1
(43) Pub. Date: Mar. 24, 2016

(54) ORGANIC LIGHT EMITTING DIODE DEVICE

(71) Applicant: SAMSUNG DISPLAY CO., LTD., Yongin-City (KR)

(72) Inventors: Chan Young PARK, Yongin-si (KR); Gee Bum KIM, Suwon-si (KR)

(21) Appl. No.: 14/685,105

(22) Filed: Apr. 13, 2015

(30) Foreign Application Priority Data
Sep. 19, 2014 (KR) 10-2014-0124800

(51) Int. Cl. H01L 51/52; H01L 27/32

(52) U.S. Cl. CPC H01L 51/5271; H01L 27/3246; H01L 51/5275; H01L 51/5246; H01L 51/5284; H01L 2251/5315; H01L 2251/5361

(57) ABSTRACT

An organic light emitting diode (OLED) display includes a first substrate, a first electrode on the first substrate, a pixel defining layer having a first aperture exposing the first electrode, an organic light emitting layer on the first electrode, a second electrode on the organic light emitting layer, a second substrate that faces the first substrate, and a first filler and a second filler between the first and second substrates. The first filler is on the first aperture and has a higher refractive index than the second filler.

### CROSS-REFERENCE TO RELATED APPLICATION

Korean Patent Application No. 10-2014-0124800, filed on Sep. 19, 2014, in the Korean Intellectual Property Office, and entitled: “Organic Light Emitting Diode Device,” is incorporated by reference herein in its entirety.

### BACKGROUND

1. Field

Embodiments relate to an organic light emitting diode display.

2. Description of the Related Art

An organic light emitting diode (OLED) display is a self-emission type display device that displays an image with an OLED that emits light. The OLED display may not require a separate light source, which is different from a liquid crystal display (LCD), and thus may have relatively reduced thickness and weight. Further, the OLED display may exhibit excellent properties such as low power consumption, high luminance, and high speed of response, and thus has drawn attention as a display device of the next generation.

The OLED may generally include a hole injection electrode, an organic light emitting layer, and an electron injection electrode. A hole injected from the hole injection electrode and an electron injected from the electron injection electrode are combined with each other to form an exciton. The OLED emits lights by energy generated when the exciton falls from an excited state to a ground state.

### SUMMARY

Embodiments are directed to an organic light emitting diode (OLED) display including a first substrate, a first electrode on the first substrate, a pixel defining layer having a first aperture exposing the first electrode, an organic light emitting layer on the first electrode, a second electrode on the organic light emitting layer, a second substrate that faces the first substrate, and a first filler and a second filler between the first and second substrates. The first filler is on the first aperture and has a higher refractive index than the second filler.

The first filler may include first and second inclined surfaces forming border lines with respect to the second filler.

A distance between the first and second inclined surfaces of the first filler may become narrower in a direction from the first substrate to the second substrate.

The first filler may have a refractive index of about 1.5 to about 2.5.

The second filler may have a refractive index of about 1.0 to about 1.4.

The OLED display may further include a thin film encapsulation layer on the second electrode.

The OLED display may further include a black matrix on the second substrate, the black matrix covering at least a part of an upper surface of the second filler.

The black matrix may include a second aperture, the second aperture exposing an upper surface of the first filler.

The second aperture may have a smaller size than the first aperture.

Embodiments are also directed to an organic light emitting diode (OLED) display including a first substrate, a first electrode on the first substrate, a pixel defining layer on the first substrate, the pixel defining layer having a first aperture exposing the first electrode, an organic light emitting layer on the first electrode, a second electrode on the organic light emitting layer, a second substrate that faces the first substrate, and a filler and an air layer between the first and second substrates. The filler is on the first aperture. The filler has a higher refractive index than the air layer.

The filler may include first and second inclined surfaces forming border lines with respect to the air layer.

A distance between the first and second inclined surfaces of the filler may become narrower in a direction from the first substrate to the second substrate.

The filler may have a refractive index of about 1.5 to about 2.5.

The OLED display may further include a thin film encapsulation layer on the second electrode.

The OLED display may further include a black matrix on the second substrate, the black matrix having a second aperture, the second aperture exposing an upper surface of the filler.

The second aperture may have a smaller size than the first aperture.

### BRIEF DESCRIPTION OF THE DRAWINGS

Features will become apparent to those of skill in the art by describing in detail exemplary embodiments with reference to the attached drawings in which:

FIG. 1 illustrates a plan view depicting a pixel of an OLED display according to one embodiment;

FIG. 2 illustrates a cross-sectional view taken along line I-I′ of FIG. 1 according to one embodiment; and

FIG. 3 illustrates a cross-sectional view taken along line I-I′ of FIG. 1 according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “between” two layers, it can be the only layer between the two layers, or one or more intervening layers may also be present. Like reference numerals refer to like elements throughout.

Throughout the specification, when an element is referred to as being “connected” to another element, the element is “directly connected” to the other element, or “electrically connected” to the other element with one or more intervening elements interposed therebetween.

Unless otherwise defined, all terms used herein (including technical and scientific terms) have the same meaning as commonly understood by those skilled in the art to which this subject matter pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

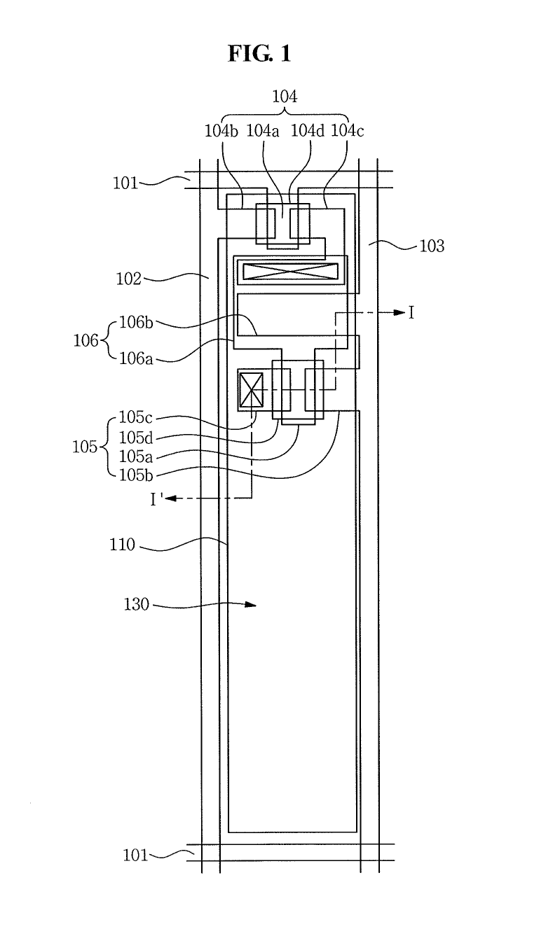

Referring to FIG. 1, in the OLED display according to an embodiment, a plurality of pixel regions are defined by border lines of a gate line 101 disposed along one direction and data and common power lines 102 and 103 insulated from and intersecting the gate line 101. One pixel may be disposed in each pixel region. In some implementations, the pixel region may be defined by the pixel defining layer as described below, and a plurality of pixels may be disposed in each pixel region.

In the OLED display according to an embodiment, a pixel may have a 2TFT-1Cap structure, which includes two thin film transistors (TFTs) that are switching and driving thin film transistors 104 and 105, respectively, and a capacitor (CAP) 106. In some implementations, one pixel may include three or more TFTs and two or more capacitors.

The switching TFT 104 may select a pixel to perform light emission. The switching TFT 104 may include a switching gate electrode 104a connected to the gate line 101, a switching source electrode 104b connected to the data line 102, a switching drain electrode 104c connected to the first capacitor plate 106a, and a switching semiconductor layer 104d.

The driving TFT 105 may apply a driving power, which allows an organic light emitting layer 130 in a pixel selected by the switching TFT 104 to emit light. The driving TFT 150 may include a driving gate electrode 105a connected to the first capacitor plate 106a, a driving source electrode 105b connected to the common power line 103, a driving drain electrode 105c connected to the first electrode 110, and a driving semiconductor layer 105d.

The capacitor 106 may include first and second capacitor plates 106a and 106b.

The first capacitor plate 106a may be connected to the switching drain electrode 104c and the driving gate electrode 105a and the second capacitor plate 106b may be connected to the common power line 103. Capacitance of the capacitor 106 may be determined by electric charges stored in the capacitor 106 and voltage across the first and second capacitor plates 106a and 106b.

A voltage equivalent to a difference between a data voltage applied from the switching TFT 104 and a common voltage applied from the common power line 103 to the driving TFT 105 may be stored in the capacitor 106, and a current corresponding to the voltage stored in the capacitor 106 may flow to the organic light emitting layer 130 through the driving TFT 105, such that the organic light emitting layer 130 may emit light.

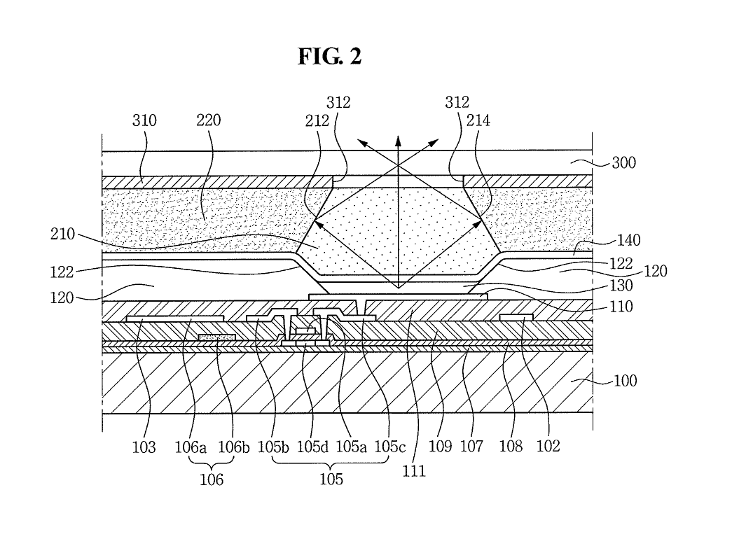

Referring to FIG. 2, the OLED display according to an embodiment may include a first substrate 100, a first electrode 110 on the first substrate 100, a pixel defining layer 120 including a first aperture 122 that exposes the first electrode 110, the organic light emitting layer 130 on the first electrode 110, a second electrode 140 on the organic light emitting layer 130, a second substrate 300 disposed to face the first substrate 100, and first and second fillers 210 and 220 between the first and second substrates 100 and 300.

The first substrate 100 may be made of an insulative substrate selected from glass, quartz, ceramic, plastic or the like, as examples. In some implementations, the first substrate 100 may be made of a metal material such as stainless steel or the like.

A buffer layer 107 including an organic or inorganic layer may be formed on the first substrate 100. The buffer layer 107 may reduce or prevent infiltration of undesirable elements such as impurities or moisture and may planarize a surface of the first substrate 100. Further, on the first substrate 100, a gate insulating layer 108 may be disposed between the gate electrodes 104a and 105a and semiconductor layers 104d and 105d, an interlayer insulating layer 109 may be disposed between the first and second capacitor plates 106a and 106b, and a planarization layer 111 may cover the common power lines 102 and 103, the first capacitor plate 106a, the driving source electrode 105b, and the driving drain electrode 105c.

The first electrode 110, the organic light emitting layer 130, and the second electrode 140 may be sequentially laminated on the first substrate 100. The first electrode 110 may be an anode that serves to inject holes, and the second electrode 140 may be a cathode that serves to inject electrons. In other implementations, the first electrode may be a cathode and the second electrode may be an anode.

At least one of a hole injection layer and a hole transporting layer may be disposed between the first electrode 100 and the organic light emitting layer 130. At least one of an electron transporting layer and an electron injection layer may be disposed between the second electrode 140 and the organic light emitting layer 130. A thin film encapsulation layer may be further disposed on the second electrode 140. The thin film encapsulation layer may have a structure where at least one organic layer and at least one inorganic layer are alternately disposed.

The pixel defining layer 120 may have a first aperture 122. The first electrode 110 may be exposed in the first aperture 122. The first electrode 110, the organic light emitting layer 130, and the second electrode 140 may be sequentially laminated in the first aperture 122 of the pixel defining layer 120. The organic light emitting layer 130 and the second electrode 140 may be disposed on the pixel defining layer 120.

According to an embodiment, the organic light emitting display device may be a top emission type according to an embodiment. The first electrode 110 may be formed of a reflective layer and the second electrode 140 may be formed of a transflective layer. Light generated from the organic light emitting layer 130 may be emitted onto the second substrate 300 through the second electrode 140.

The reflective layer and the transflective layer may include one or more metals selected from magnesium (Mg), silver (Ag), gold (Au), calcium (Ca), lithium (Li), chromium (Cr), and aluminum (Al) or metal alloys thereof. Whether an electrode is a transflective type or a reflective type may depend on the thickness of the layer. Generally, the transflective electrode may have a thickness of about 200 nm or less.

The first electrode 110 may further include a transparent conductive layer. The transparent conductive layer may be formed of one or more transparent conductive oxides (TCO) such as indium tin oxide (ITO), indium zinc oxide (IZO), zinc oxide (ZnO) or indium oxide (In₂O₃).

The first electrode 110 may have a single-layer structure including a reflective layer, a double-layer structure including a reflective layer and a transparent conductive layer, or a triple-layer structure where a transparent conductive layer, a reflective layer, and a transparent conductive layer are sequentially laminated, as examples. In some implementations, the first electrode may have a structure including a transparent conductive layer.

The second electrode 140 may have a structure including a transparent conductive layer. When the second electrode 140 is formed of a transparent conductive layer, the second electrode 140 may be an anode injecting holes and the first electrode 110 may be a cathode formed of reflective layer.

The first and second fillers 210 and 220 may be disposed in a separated space between the first and second substrates 100 and 300. The first filler 210 may have a higher refractive index than the second filler 220, thereby forming a wave guide of light emitted from the organic light emitting layer 130.

The first filler 210 may be disposed on the first aperture 122 and may include first and second inclined surfaces 212 and 214, which may form a border line with respect to the second filler 220. A distance between the first and second inclined surfaces 212 and 214 may become narrower in a direction from the first substrate 100 to the second substrate 300. In other implementations, the distance between the first and second inclined surfaces may be equal from the first substrate 100 to the second substrate 300.

The first filler 210 may have a refractive index of about 1.5 to about 2.5.

The first filler 210 may be a silicon compound, poly (methyl methacrylate)

(PMMA) or an alloy thereof, as examples. In some implementations, the first filler may be an organic or inorganic materials having a refractive index of about 1.5 to about 2.5.

For instance, the organic material having a refractive index of about 1.5 to about 2.5 may include poly (3,4-ethylenedioxythiophene) (PEDOT), 4,4′-bis[N-(3-methylphenyl)-N-phenylamino]biphenyl (TPD), 4,4′, 4″-tris [(3-methylphenyl) phenylamino]triphenylamine (m-MTDATA), 1,3,5-tris[N,N-bis(2-methylphenyl) amino]-benzene (o-MTDAB), 1,3,5-tris[N,N-bis(3-methylphenyl)amino]-benzene (m-MTDAB), 1,3,5-tris[N,N-bis(4-methylphenyl)amino]-benzene (p-MTDAB), 4,4′-bis[N, N-bis(3-methylphenyl)-amino]-diphenylmethane (BPPM), 4,4′-dicarbazolyl-1,1′-biphenyl (CBP), 4,4′,4″-tris(N-carbazole) triphenyl amine (TCTA), 2,2′,2″-(1,3,5-benzene-tolyl) tris-[1-phenyl-1H-benzoimidazol](TPBI), and 3-(4-biphenylyl)-4-phenyl-5-t-butylphenyl-1,2,4-triazole (TAZ), or the like.

Further, the inorganic materials having a refractive index of about 1.5 to about 2.5 or less may include a zinc oxide, a titanium oxide, a zirconium oxide, a niobium oxide, a tantalum oxide, a tin oxide, a nickel oxide, a silicon nitride, an indium nitride, a gallium nitride, or the like.

The second filler 220 may have a refractive index of about 1.0 to about 1.4.

The second filler 220 may include an acrylic, a polyimide, a polyamide, or an alloy thereof, as examples. In some embodiments, the second filler may be an organic or inorganic material having a refractive index of about 1.0 or more and 1.4 or less.

In the case of a top-emission type OLED display, total internal reflection may occur due to a difference in refractive indices at an inter-layer interface when light emitted from the organic light emitting layer 130 propagates toward the second substrate 200, such that the light may be reflected inwardly or sidewardly, which could result in a deterioration of light efficiency.

In the OLED display according to an embodiment, the first filler 210 that has a high refractive index may be disposed on the first aperture 122 of the pixel defining layer 120 and the second filler 220 that has a low refractive index may be disposed in other areas. Accordingly, light propagating sidewardly from the organic light emitting layer 130 may be reflected off the first and second inclined surfaces 212 and 214 of the first filler 210 toward the front side of the OLED display, thereby improving light efficiency. Further, an angular distribution of light emitted frontwardly from the OLED display may be widened, thereby improving a viewing angle and reducing color distortion.

The second substrate 300 may include the same material as the first substrate 100. A black matrix 310 having a second aperture 312 may be disposed on the second substrate 300.

The black matrix 310 may be configured to block ambient light. The black matrix 310 may be disposed to cover a whole upper surface of the second filler 220, for example. In some implementations, the black matrix 310 may be disposed to cover a part of the upper surface of the second filler 220.

The second aperture 312 of the black matrix 310 may expose the upper surface of the first filler 210. The second aperture 312 may have a size smaller than the first aperture 122 considering the light efficiency. Accordingly, light emitted from the organic light emitting layer 130 may pass along and through the first filler 210 and may be radiated outwardly through the second aperture 312.

External light incident on areas other than the second aperture 312 may be absorbed by the black matrix 310. External light incident on the second aperture 312 may be trapped inside the first filler 210. Accordingly, the OLED display according to an embodiment may reduce external light reflection without using a separate polarizer.

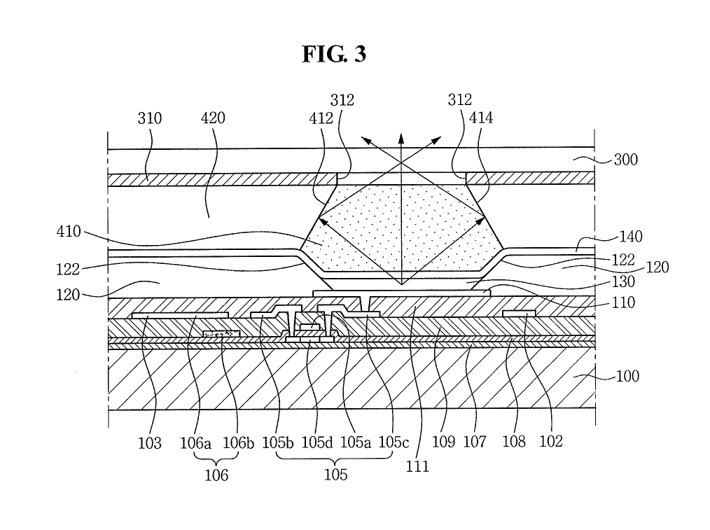

Referring to FIG. 3, an OLED display according to another embodiment may have the same configuration as the OLED display illustrated in FIG. 2, except for including an air layer instead of the second filler between the first and second substrates. The description of similar components will not be repeated for sake of brevity.

A filler 410 may have the same refractive index and may be formed of the same material as the first filler 210 illustrated in FIG. 2. Further, the filler 410 may have a refractive index higher than the air layer 420, thereby forming an optical waveguide for light emitted from an organic light emitting layer 130.

The OLED display according to this embodiment may have a larger refractive-index difference between the filler 410 and the air layer 420 compared to the refractive-index difference between the first and second fillers 210 and 220 illustrated in FIG. 2. This larger refractive-index difference by virtue of the filler 410 may result in an improved optical waveguide effect.

By way of summation and review, embodiments provide an OLED display improved with respect to a viewing angle, light efficiency, and color distortion.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An organic light emitting diode (OLED) display, comprising:
a first substrate;
a first electrode on the first substrate;
a pixel defining layer having a first aperture exposing the first electrode;
an organic light emitting layer on the first electrode;
a second electrode on the organic light emitting layer;
a second substrate that faces the first substrate; and
a first filler and a second filler between the first and second substrates,
wherein the first filler is on the first aperture and has a higher refractive index than the second filler.

2. The OLED display as claimed in claim 1, wherein the first filler includes first and second inclined surfaces forming border lines with respect to the second filler.

3. The OLED display as claimed in claim 2, wherein a distance between the first and second inclined surfaces of the first filler becomes narrower in a direction from the first substrate to the second substrate.

4. The OLED display as claimed in claim 1, wherein the first filler has a refractive index of about 1.5 to about 2.5.

5. The OLED display as claimed in claim 1, wherein the second filler has a refractive index of about 1.0 to about 1.4.

6. The OLED display as claimed in claim 1, further comprising a thin film encapsulation layer on the second electrode.

7. The OLED display as claimed in claim 1, further comprising a black matrix on the second substrate, the black matrix covering at least a part of an upper surface of the second filler.

8. The OLED display as claimed in claim 7, wherein the black matrix has a second aperture, the second aperture exposing an upper surface of the first filler.

9. The OLED display as claimed in claim 8, wherein the second aperture has a smaller size than the first aperture.

10. An organic light emitting diode (OLED) display, comprising:
a first substrate;
a first electrode on the first substrate;
a pixel defining layer on the first substrate, the pixel defining layer having a first aperture exposing the first electrode;
an organic light emitting layer on the first electrode;
a second electrode on the organic light emitting layer;
a second substrate that faces the first substrate; and
a filler and an air layer between the first and second substrates,
wherein the filler is on the first aperture and has a higher refractive index than the air layer.

11. The OLED display as claimed in claim 10, wherein the filler includes first and second inclined surfaces forming border lines with respect to the air layer.

12. The OLED display as claimed in claim 11, wherein a distance between the first and second inclined surfaces of the filler becomes narrower in a direction from the first substrate to the second substrate.

13. The OLED display as claimed in claim 10, wherein the filler has a refractive index of about 1.5 to about 2.5.

14. The OLED display as claimed in claim 10, further comprising a thin film encapsulation layer on the second electrode.

15. The OLED display as claimed in claim 10, further comprising a black matrix on the second substrate, the black matrix having a second aperture, the second aperture exposing an upper surface of the filler.

16. The OLED display as claimed in claim 15, wherein the second aperture has a smaller size than the first aperture.
